(19) United States
(12) Patent Application Publication
(10) Pub. No.: US 2012/0199980 A1
(43) Pub. Date: Aug. 9, 2012

(54) INTEGRATED CIRCUITS HAVING INTERCONNECT STRUCTURES AND METHODS FOR FABRICATING INTEGRATED CIRCUITS HAVING INTERCONNECT STRUCTURES

(75) Inventors: Egon R. PFUETZNER, Dresden (DE); Torsten HUISINGA, Dresden (DE); Jens HAHN, Dresden (DE)

(73) Assignee: GLOBALFOUNDRIES INC., Grand Cayman (KY)

(21) Appl. No.: 13/022,414

(22) Filed: Feb. 7, 2011

(51) Int. Cl. H01L 23/48; H01L 21/768

(52) U.S. Cl. 257/774; 438/643; 257/E21.575; 257/E23.011

(57) ABSTRACT

Integrated circuits and methods for fabricating an integrated circuit are provided. A conductive feature is formed in a semiconductor substrate. A layer of ULK or LK dielectric material is formed overlying the conductive feature. An opening having a sidewall surface is etched through the layer of ULK or LK dielectric material. Damage on the sidewall surface resulting from the etching is removed. An ULK or LK dielectric liner is formed overlying the sidewall surface. The ULK or LK dielectric liner along the bottom of the opening is removed to expose the conductive feature. The opening is filled with a metal fill material contacting the conductive feature.

### FIELD OF THE INVENTION

The present invention generally relates to integrated circuits and methods for fabricating integrated circuits, and more particularly relates to integrated circuits having interconnect structures and methods for fabricating integrated circuits having interconnect structures.

### BACKGROUND OF THE INVENTION

During the front end-of-the-line (FEOL) semiconductor fabrication process, a plurality of semiconductor devices (e.g., transistors, resistors, and the like) is formed on a semiconductor substrate. During the back end-of-the-line (BEOL) semiconductor fabrication process, the semiconductor devices are interconnected by interconnect structures to form a plurality of integrated circuits (ICs) on the semiconductor substrate. Efficient interconnection requires formation of multilevel or multilayered schemes, such as, for example, single or dual Damascene wiring structures.

The continued decrease of feature sizes on integrated circuits has increased circuit performance and yield at a lower cost per function on chips. However, as feature size decreases, the resistance-capacitance (RC) delay associated with interconnect structures becomes the dominant performance limiting factor. The RC delay results from an increased resistance arising from the narrowing of the interconnect structures and an increased capacitance arising from the closer proximity of the interconnect structures. An increase in the RC delay has a negative impact on the speed and power consumption of IC devices, thus decreasing its reliability.

Ultra-low K (hereinafter “ULK”) and low K (hereinafter “LK”) dielectric materials have been used in the semiconductor industry in back-end-of-line (BEOL) processes for reducing RC delay. As used herein, “ultra-low K (ULK) dielectric materials” and “low K (LK) dielectric materials” are typically dielectric materials having dielectric constants below about 2.7 (ULK) and below about 3.0 (low-K), respectively. Lower k-values in inorganic materials can be achieved by adding carbon-containing moieties to reduce polarizability, thereby reducing the k-value.

ULK and LK dielectric materials can get damaged by plasma etching, resist ashing, and/or cleaning operations during formation of the interconnect structures. During such operations, at least a portion of the carbon-containing moieties can be removed resulting in ULK and LK dielectric materials having reduced hydrophobicity. When the carbon-containing moieties are removed, the Si—C bonds are replaced with Si—OH (“silanol”) bonds or groups and the resulting damaged dielectric layer loses its hydrophobicity as water molecules from the atmosphere form strong hydrogen-bonding interactions with the silanol groups. The presence of water which has a k-value of about 70 results in a significant increase in the k-value of the dielectric material.

For example, the Damascene process involves etching a pattern of openings for interconnect structures (i.e., vias and trenches) in the surface of an insulating layer such as a dielectric layer, and then filling the openings with copper during a metallization sequence, after forming of a diffusion barrier layer on the sidewall surface of the interconnect structures, as hereinafter described. Conventional processes for fabricating interconnect structures use a photoresist and lithography to provide openings for the interconnect structures within the dielectric layer. The patterned photoresist formed during the lithographic step is stripped by a plasma-based process which tends to damage the exposed surfaces in the openings formed in the dielectric material. As noted previously, carbon in the damaged portions of the dielectric material is depleted, and the dielectric layer becomes hydrophilic contributing to degradation (increase) of the dielectric constant of the damaged surface portions, negatively impacting RC delay and circuit performance.

The diffusion barrier layer is deposited on the sidewall surface of the openings to prevent the copper from diffusing into the dielectric material. One problem is that a damaged dielectric surface requires a thicker diffusion barrier layer to ensure that there are no thin patches through which copper can diffuse. It can be difficult to obtain continuous metal barrier coverage over damaged dielectric surfaces and any discontinuity in the diffusion barrier layer allows copper to diffuse through. The thicker diffusion barrier layer, however, partially offsets the advantage of the ULK and LK dielectric materials by increasing the resistance capacitance (RC) delay. Also of major concern during formation of the interconnect structures is the poor adhesion between damaged dielectric surfaces and the diffusion barrier layer that can result in peeling problems during metal fill and the subsequent planarization.

Accordingly, it is desirable to provide integrated circuits having interconnect structures and methods for fabricating integrated circuits having interconnect structures. In addition, it is desirable to fabricate integrated circuits having interconnect structures that incorporate dielectric materials to take advantage of the benefits associated with reduced resistance capacitance delay while at the same time overcoming the issues caused by damage done to dielectric layers during formation of the interconnect structures, thus enabling the use of a thinner diffusion barrier layer in the openings formed in the dielectric layer, providing better adhesion between the dielectric layer and the diffusion barrier layer, and reducing undercut between the cap dielectric layer and the dielectric layer. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

Methods are provided for fabricating an integrated circuit. In accordance with one exemplary embodiment, the method includes forming a conductive feature in a semiconductor substrate. A layer of ULK or LK dielectric material is formed overlying the conductive feature. An opening having a sidewall surface is etched through the layer of ULK or LK dielectric material. Damage on the sidewall surface resulting from the etching is removed. An ULK or LK dielectric liner is formed overlying the sidewall surface. The ULK or LK dielectric liner along the bottom of the opening is removed to expose the conductive feature. The opening is filled with a metal fill material contacting the conductive feature.

Methods are provided for fabricating an integrated circuit in accordance with yet another exemplary embodiment of the present invention. The method includes providing a semiconductor substrate. An ULK or LK dielectric layer is formed overlying the semiconductor substrate. A cap dielectric layer is formed overlying the ULK or LK dielectric layer. An opening in the cap dielectric layer and the ULK or LK dielectric layer is formed thereby damaging a sidewall surface of the opening in the ULK or LK dielectric layer. The damaged sidewall surface of the ULK or LK dielectric layer is removed. An ULK or LK dielectric liner is formed over the cap dielectric layer and within the opening. The ULK or LK dielectric liner is removed along the bottom of the opening to expose an underlying conductive feature. The opening is filled with a metal fill material.

An integrated circuit is provided in accordance with yet another exemplary embodiment of the present invention. The integrated circuit includes a semiconductor substrate. An insulating layer on the semiconductor substrate has a conductive feature therein. An ULK or LK dielectric layer overlies the insulating layer having a metallic feature therein connected to the conductive feature. The metallic feature is a filled opening in the ULK or LK dielectric layer filled with a metal fill material. An ULK or LK dielectric liner overlies the sidewall surface of the filled opening of the metallic feature, excluding along a bottom of the filled opening.

### BRIEF DESCRIPTION OF THE DRAWINGS

The present invention will hereinafter be described in conjunction with the following drawing figures, wherein like numerals denote like elements, and

FIG. 1 is a flow diagram of a method for fabricating an integrated circuit, according to exemplary embodiments of the present invention;

FIG. 2 illustrates, in cross-section, an exemplary initial integrated circuit with an opening in an ULK or LK dielectric layer having a damaged sidewall surface in the opening; and

FIGS. 3 to 7 illustrate, in cross section, the integrated circuit of FIG. 2 after subsequent processing in the method for fabricating an integrated circuit having an interconnect structure, according to exemplary embodiments of the present invention.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

Various exemplary embodiments of the present invention are directed to integrated circuits and methods for fabricating integrated circuits having interconnect structures. As noted previously, forming interconnect structures of an integrated circuit often results in damage to dielectric layers. The damaged dielectrics include ultra-low K (ULK) dielectric materials having a dielectric constant less than about 2.7 and low-k (LK) dielectric materials having a dielectric constant less than about 3.0. All dielectric constants referred to herein are relative to a vacuum. The ULK and LK dielectrics may be damaged, for example, by etching a pattern of openings for the interconnect structures (i.e., trenches and vias), in the surface of the ULK or LK dielectric layer prior to metallization of the etched openings with a metal fill material to form a metallic feature. Damage to the ULK or LK dielectric layer may also occur by other etching processes, by resist ashing, and/or cleaning operations of the integrated circuits. Formation of a ULK or LK dielectric liner including in the etched opening helps restore the resistance capacitance (RC) delay and dielectric constant of the dielectric layer, thus maintaining circuit performance. In addition, such liner enables the use of a thinner diffusion barrier layer, provides better adhesion between the dielectric layer and the diffusion barrier layer, if present, and reduces undercut between a cap dielectric layer and the dielectric layer to reduce current leakage. Thus, the integrated circuit may incorporate ULK and LK dielectric materials to take advantage of the benefits associated with reduced resistance capacitance delay while at the same time overcoming the issues caused by damage to dielectric layers.

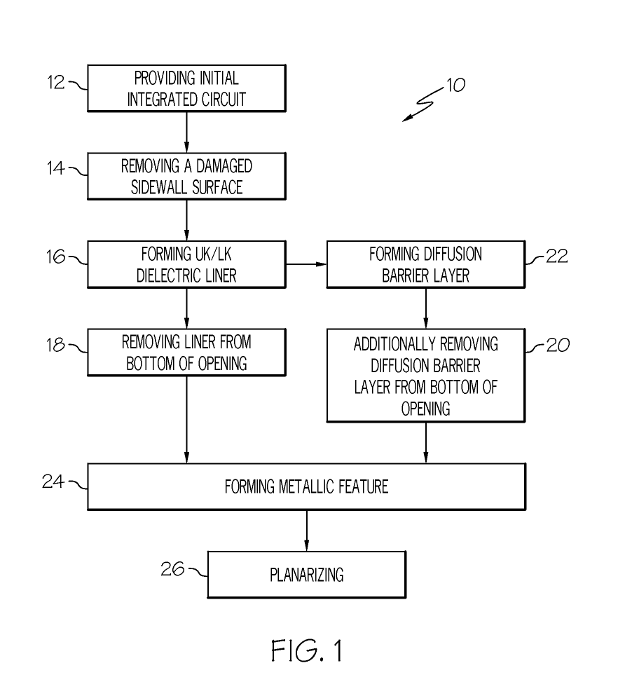

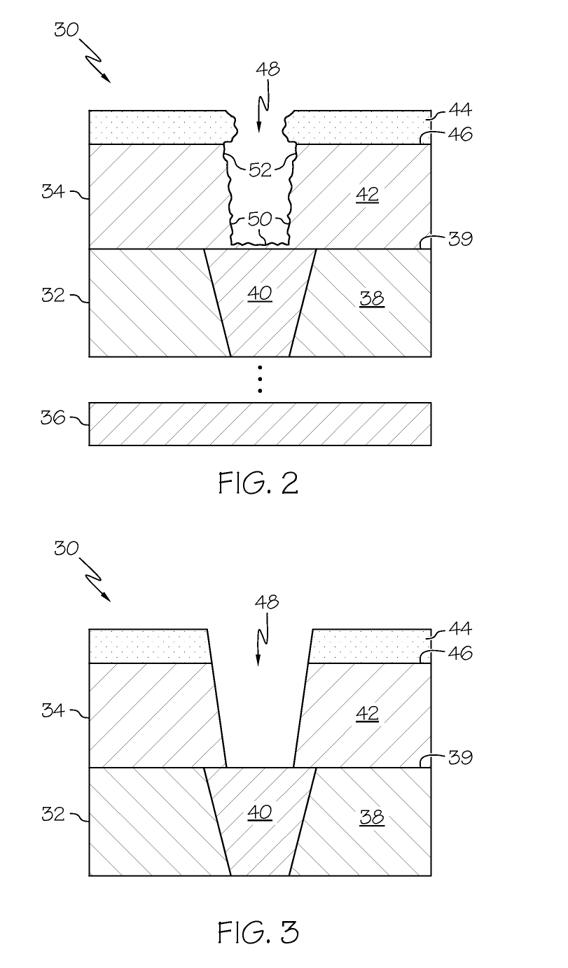

Referring now to FIG. 1, a method 10 for fabricating an integrated circuit having an interconnect structure begins by providing an integrated circuit 30 (step 12). An initial integrated circuit is illustrated in FIG. 2. The initial integrated circuit is made using standard semiconductor processing that is well known in the art. FIG. 2 illustrates an exemplary initial integrated circuit including a lower interconnecting level 32 and an overlying ultra-low K (ULK) or a low K (LK) dielectric layer 42 through which an upper interconnecting level 34 will be formed. The lower interconnecting level 32 includes a semiconductor substrate 36, an insulating layer 38 over the semiconductor substrate, and a conductive feature 40 formed in the insulating layer. The semiconductor substrate is made of a semiconductor material such as monocrystalline silicon, polycrystalline silicon, silicon-germanium, or the like and may include insulating layers, diffusion barrier layers, conductive layers, and the like as well as circuitry and other structures including one or more semiconductor devices such as transistors, capacitors, resistors, and the like (not shown). For simplicity, the semiconductor substrate will not be shown in subsequent drawings. The conductive feature 40 may be metal lines of copper, tungsten, aluminum, silver, gold, and the like. The conductive feature can also be formed of other conductive materials such as doped polysilicon. The conductive feature may be connected to other underlying features (not shown), such as other metal lines, vias, contact plugs, or silicide regions of MOS devices.

Still referring to FIG. 2, the upper interconnecting level 34 is formed on the planarized surface of the lower interconnecting level. The upper interconnecting layer includes the ultra-low K (ULK) or a low K (LK) dielectric layer 42 formed overlying the insulating layer 38 and the conductive feature 40. The ULK dielectric layer is formed of ULK dielectric materials. The preferred ULK dielectric materials include, for example, SiOC, silsesquioxanes, carbon-doped oxides (i.e., organosilicates), or the like. If an LK layer is formed, the LK dielectric layer is formed of LK dielectric materials including, for example, SiCOH.

A cap dielectric layer 44 is formed over and contacting a top surface 46 of the ULK or LK dielectric layer 42. In an embodiment, the cap dielectric layer may be formed from SiO₂. The cap dielectric layer may be formed utilizing conventional formation processes such as, for example, CVD, PECVD, ALD, or the like. The thickness of the cap dielectric layer may vary depending on the process and material used for its formation. The cap dielectric layer serves as a hard mask during subsequent etching and planarization of the ULK or LK dielectric layer, as hereinafter described.

An opening 48 for a via or trench (i.e., the interconnect structure) is formed in the cap dielectric layer 44 and in the surface of the ULK or LK dielectric layer 42 where the interconnect structure is to be formed. As is known in the art, a photoresist layer (not shown) is formed and patterned over the ULK or LK dielectric layer and the cap dielectric layer to mask the regions to be protected. The opening is then formed by etching the cap dielectric layer and the ULK or LK dielectric layer using an etching process such as a reactive ion etch (RIE). The patterned photoresist layer is then removed by a stripping step using a plasma containing oxygen, carbon monoxide, carbon dioxide, nitrogen, hydrogen, ammonia, argon, helium, or other gases capable of removing the organic photoresist layer. Such stripping process can result in damaging a sidewall surface 50 of the ULK or LK dielectric layer in the opening. In addition, as the etch rates of the cap dielectric layer and the ULK or LK dielectric layer are different, etching of the opening also causes an undercut 52 between the ULK or LK dielectric layer 42 and the cap dielectric layer 44.

Referring again to FIG. 1, method 10 continues by removing the damaged sidewall surface 50 of the ULK or LK dielectric layer resulting from the etching (step 14). FIG. 3 illustrates a portion of the integrated circuit after removal of the damaged sidewall surface. The damaged sidewall surface in the opening in the ULK or LK dielectric layer may be removed, for example, by wet cleaning in dilute hydrofluoric acid (HF), plasma cleaning, or the like.

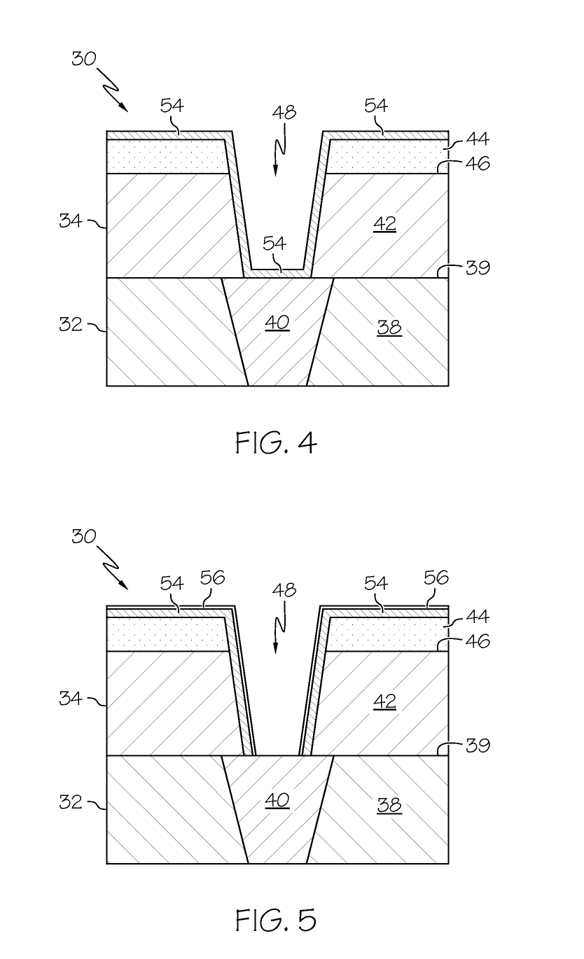

Referring again to FIG. 1, method 10 continues by forming an ULK or LK dielectric liner 54 over the cap dielectric layer and within the opening 48 (step 16), including at least partial filling of the undercut 52 between the ULK or LK dielectric layer and the cap dielectric layer. The ULK or LK dielectric liner overlies the sidewall surface of the opening. FIG. 4 illustrates the integrated circuit after formation of the ULK or LK dielectric material liner 54. The preferred dielectric materials for the liner include silicon oxide-based material, such as SiCOH. The ULK or LK dielectric material liner may be deposited, for example, by a CVD process or the like. The minimum thickness of the liner is about 0.5 nm. The maximum thickness of the liner should allow enough metal fill in the at least one opening to provide the necessary connectivity, as hereinafter described. The dielectric material of the liner may be the same dielectric material or a different dielectric material than the ULK or LK dielectric layer. The density and elemental compositions of the liner and ULK or LK dielectric layer may be the same or different.

Referring again to FIG. 1, the ULK or LK dielectric liner 54 along the bottom of the opening is then completely or partially removed (step 18). The ULK or LK dielectric liner along the bottom of the opening may be removed prior to deposition of a diffusion barrier layer 56 and prior to metallization, as hereinafter described. The ULK or LK liner along the bottom of the opening 48 may be removed by anisotropic etching in a plasma reaction chamber using an oxide etchant, for example, CHF₃, CF₄, SF₆, and Ar. Removal may be done in the same piece of equipment as either was used for the formation of the liner or that will be used for the metallization as hereinafter described, or a different piece of equipment.

Alternatively, in accordance with another exemplary embodiment, the ULK or LK liner along the bottom of the opening may be removed and the diffusion barrier layer 56 additionally removed (step 20 in FIG. 1) during metallization after forming the diffusion barrier layer 56, as hereinafter described. The diffusion barrier layer 56 is formed overlying the ULK or LK dielectric material liner including within the at least one opening prior to metal fill (step 22 in FIG. 1). The diffusion barrier layer substantially prevents the metal fill materials, particularly copper, from diffusing into the ULK or LK dielectric layer. As noted previously, some metals, particularly copper, diffuse rapidly in many dielectric materials and also ionize and drift in these materials under the influence of electrical fields. Such diffusion and drift threaten circuit reliability through increased dielectric leakage currents and eventually, dielectric breakdown. The diffusion barrier layer also prevents impurities in the ULK or LK dielectric layer from diffusing into the metal fill materials. The diffusion barrier layer has significantly higher resistivity than copper itself and so a diffusion barrier layer that is as thin as possible is formed to avoid an unacceptable increase in the effective resistivity of the copper. In an embodiment, the diffusion barrier layer may have a total thickness of about 1 nm to about 10 nm. The diffusion barrier layer is thinner than the ULK or LK dielectric liner. The diffusion barrier layer is formed by a deposition process such as, for example, physical vapor deposition (PVD), chemical vapor deposition (CVD), or other suitable methods to ensure adequate sidewall coverage. For ease of illustration, the diffusion barrier layer is shown as one layer, but it should be appreciated that the diffusion barrier layer may include multiple layers. The diffusion barrier layer may include, for example, a layer of tantalum, or any other material that can serve as a barrier to prevent the metal fill material from diffusing into the ULK or LK dielectric layer. As noted previously, the ULK or LK dielectric liner along the bottom of the opening may be removed and the diffusion barrier layer additionally removed after forming the diffusion barrier layer 56 in which case the combined ULK or LK dielectric liner 54 and diffusion barrier layer 56 may be etched back using a plasma etchant which is capable of etching both the diffusion barrier layer material and the dielectric material liner at approximately the same rate. FIG. 5 illustrates an embodiment in which the ULK or LK dielectric liner and diffusion barrier layer along the bottom of the opening have been completely removed to expose the underlying conductive feature 40. While formation of a diffusion barrier layer has been described, it is to be understood that a diffusion barrier layer may be unnecessary if the metal fill material is not susceptible to diffusion into the ULK or LK dielectric layer.

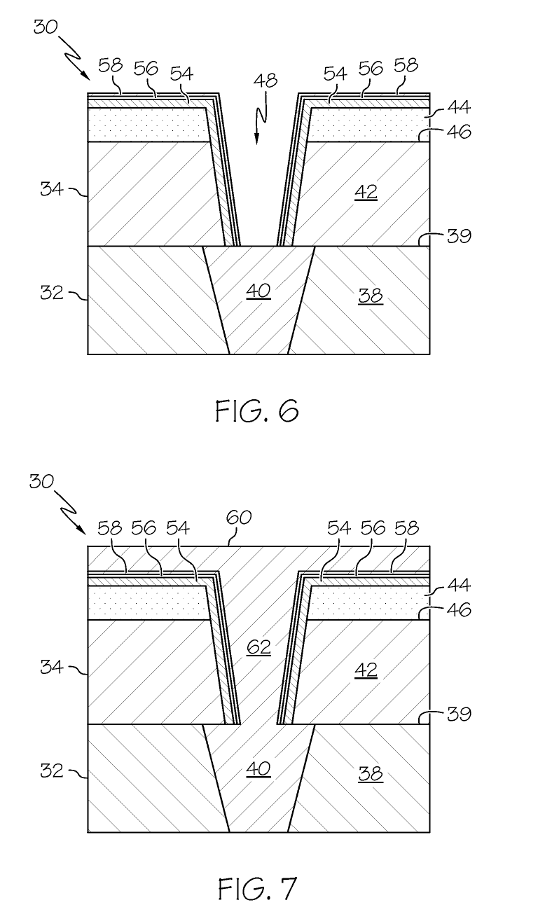

Referring again to FIG. 1, and as known in the art, the method continues with forming a metallic feature 62 in the ULK or LK dielectric layer by filling the opening with a metal fill material contacting the conductive feature (step 24). FIGS. 6 and 7 respectively illustrate forming an exemplary metallic feature in the ULK or LK dielectric layer by forming a copper seed layer 58 over the diffusion barrier layer 56 (FIG. 6), and then forming a conductive metal material layer 60 over the copper seed layer 58 including substantially filling the opening with copper (FIG. 7). The copper seed layer may be formed using a non-electrolytic process, such as PVD or the like. The conductive metal material layer 60 is formed with metal fill materials such as, for example, copper, aluminum, tungsten, silver, gold, and/or other well-known alternatives using techniques such as PVD, CVD, electroless plating and electrochemical deposition (ECD). FIG. 7 represents an open via bottom interconnect structure in which the metallic feature 62 directly contacts (i.e., interconnects with) the underlying conductive feature 40.

When no diffusion barrier layer is used, such as when the metal fill material is not susceptible to diffusion into the ULK or LK dielectric layer as previously described, the metallic feature is formed in the ULK or LK dielectric layer by forming the conductive metal material layer 60 over the ULK or LK dielectric liner 54 after removing the liner from the bottom of the opening. The conductive metal material layer substantially fills the opening with the metal fill material.

Referring again to FIG. 1, the conductive metal material layer may be planarized (step 26) by, for example, a chemical mechanical planarization (CMP) process as known in the art to remove metal overfill so that the integrated circuit can be integrated into a multi-level metallization package. Thereafter, standard processes may be used to complete fabrication and packaging of the integrated circuit. While formation of an interconnect structure in an upper interconnecting level has been described, it is to be appreciated that such formation may be undertaken in any interconnecting level of the integrated circuit, including but not limited to, the first interconnecting level.

From the foregoing, it is to be appreciated that fabrication of the integrated circuit with the ULK or LK dielectric liner after process damage to the ULK or LK dielectric layer permits incorporating ULK and LK dielectric materials to take advantage of the benefits associated with reduced resistance capacitance delay while at the same time overcoming the damage-related issues, namely permitting a thinner continuous diffusion barrier layer, providing better adhesion between the ULK or LK dielectric layer and the diffusion barrier layer, and reducing undercut between the cap dielectric layer and the ULK or LK dielectric layer.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method for fabricating an integrated circuit comprising:
forming a conductive feature in a semiconductor substrate;
forming a layer of ULK or LK dielectric material overlying the conductive feature;
etching an opening having a sidewall surface through the layer of ULK or LK dielectric material;
removing damage on the sidewall surface resulting from the etching;
forming an ULK or LK dielectric liner overlying the sidewall surface;
removing the ULK or LK dielectric liner along the bottom of the opening to expose the conductive feature; and
filling the opening with a metal fill material contacting the conductive feature.

2. The method of claim 1, wherein forming an ULK or LK dielectric liner comprises forming the ULK or LK dielectric liner with a dielectric material having a dielectric constant less than about 3.0.

3. The method of claim 1, wherein removing the ULK or LK dielectric liner along the bottom of the opening comprises anisotropic etching the ULK or LK dielectric liner.

4. The method of claim 3, wherein filling the opening with a metal fill material comprises forming a conductive metal material layer over the layer of ULK or LK dielectric liner after removing the ULK or LK dielectric liner along the bottom of the opening and planarizing the conductive metal material layer.

5. The method of claim 1, further comprising forming a diffusion barrier layer overlying the ULK or LK dielectric liner including within the opening prior to removing the ULK or LK dielectric liner along the bottom of the opening to expose the conductive feature.

6. The method of claim 5, wherein forming a diffusion barrier layer comprises forming the diffusion barrier layer having a thickness of about 1 nm to about 10 nm.

7. The method of claim 5, further comprising additionally removing the diffusion barrier layer along the bottom of the opening during removal of the ULK or LK dielectric liner along the bottom of the opening to expose the conductive feature.

8. The method of claim 7, wherein removing the ULK or LK dielectric liner along the bottom of the opening to expose the conductive feature and additionally removing the diffusion barrier layer along the bottom of the opening during removal of the ULK or LK dielectric liner comprise etching back the diffusion barrier layer and the ULK or LK dielectric liner.

9. The method of claim 8, wherein filling the opening with a metal fill material comprises:
forming a layer of copper seed over the diffusion barrier layer after additionally removing the diffusion barrier layer along the bottom of the opening during removal of the ULK or LK dielectric liner; and
forming a conductive metal material layer over the layer of copper seed and planarizing the conductive metal material layer.

10. A method for fabricating an integrated circuit, the method comprising:
providing a semiconductor substrate;
forming an ULK or LK dielectric layer overlying the semiconductor substrate;
forming a cap dielectric layer overlying the ULK or LK dielectric layer;
forming an opening in the cap dielectric layer and the ULK or LK dielectric layer thereby damaging a sidewall surface of the opening in the ULK or LK dielectric layer;
removing the damaged sidewall surface of the ULK or LK dielectric layer;
forming an ULK or LK dielectric liner over the cap dielectric layer and within the opening;
removing the ULK or LK dielectric liner along the bottom of the opening to expose an underlying conductive feature; and
filling the opening with a metal fill material.

11. The method of claim 10, wherein forming an ULK or LK dielectric liner comprises forming the ULK or LK dielectric liner with a dielectric material having a dielectric constant less than about 3.0.

12. The method of claim 11, wherein forming the ULK or LK dielectric layer comprises forming the ULK or LK dielectric layer with a different dielectric material than the dielectric material used in forming the ULK or LK dielectric liner.

13. The method of claim 10, wherein removing the ULK or LK dielectric liner along the bottom of the opening comprises anisotropic etching of the ULK or LK dielectric liner.

14. The method of claim 10, wherein filling the opening with a metal fill material comprises forming a conductive metal material layer over the ULK or LK dielectric liner after removing the ULK or LK dielectric liner along the bottom of the opening and planarizing the conductive metal material layer.

15. The method of claim 10, further comprising forming a diffusion barrier layer over the ULK or LK dielectric liner including within the opening prior to removing the ULK or LK dielectric liner along the bottom of the opening to expose an underlying conductive feature.

16. The method of claim 15, wherein forming a diffusion barrier layer comprises forming the diffusion barrier layer having a thickness of about 1 nm to about 10 nm.

17. The method of claim 15, further comprising additionally removing the diffusion barrier layer along the bottom of the opening during removal of the ULK or LK dielectric liner along the bottom of the opening.

18. The method of claim 17, wherein removing the ULK or LK dielectric liner and additionally removing comprise etching back the diffusion barrier layer and the ULK or LK dielectric liner.

19. The method of claim 17, wherein filling the opening with a metal fill material comprises:
forming a layer of copper seed over the diffusion barrier layer after additionally removing the diffusion barrier layer along the bottom of the opening; and
forming a conductive metal material layer over the layer of copper seed and planarizing the conductive metal material layer.

20. An integrated circuit comprising:
a semiconductor substrate;
an insulating layer on the semiconductor substrate having a conductive feature therein;
an ULK or LK dielectric layer overlying the insulating layer having a metallic feature therein connected to the conductive feature, the metallic feature comprising a filled opening in the ULK or LK dielectric layer filled with a metal fill material; and
an ULK or LK dielectric liner overlying the sidewall surface of the filled opening of the metallic feature, excluding along a bottom of the filled opening.
